(19) United States
(12) Patent Application Publication
(10) Pub. No.: US 2001/0014507 A1
(43) Pub. Date: Aug. 16, 2001

(54) METHOD OF FORMING A DUAL LOCAL OXIDATION STRUCTURE OF A MEMORY CHIP IN A SEMICONDUCTOR WAFER

(76) Inventor: JAMES JUEN HSU, SARATOGA, CA (US)

Correspondence Address: WINSTON HSU, SF. 389, FU-HO ROAD, YUNGHO CITY, TAIPEI, TW

(21) Appl. No.: 09/345,814

(22) Filed: Jul. 2, 1999

(51) Int. Cl. H01L 21/336; H01L 21/8242

(52) U.S. Cl. 438/298; 438/297; 438/241; 438/258

(57) ABSTRACT

The present invention provides a method of forming a dual local oxidation structure (LOCOS) of a memory circuit in a semiconductor wafer. The semiconductor wafer comprises a silicon substrate and non-overlapping first and second areas defined on the surface of the silicon substrate. The first area is used for forming a memory array of the memory circuit and the second area is used for forming a peripheral circuit of the memory circuit for controlling the operation of the memory array. Using this method, a pad oxide layer and a silicon nitride layer are first formed on the silicon substrate. The silicon nitride layer has a plurality of recesses extending down to the surface of the silicon substrate. The widths of the recesses in the first area are narrower than the widths of the recesses in the second area. Then, a high temperature oxidation process is performed to form a field oxide layer on the surface of the silicon substrate within each of the recesses. This method makes the field oxide layer in each of the recesses in the first area thinner than the field oxide layer in each of the recesses in the second area.

### BACKGROUND OF THE INVENTION

1. Field of the Invention

The present invention provides a method of forming a dual local oxidation (LOCOS) structure in a semiconductor wafer, and more particularly, a method of forming a dual LOCOS structure of a flash memory chip.

2. Description of the Prior Art

Flash memory chips have the advantage of being small and compact as well as having the ability to maintain data without the need for electrical current. Thus, they are usually employed in portable electronic products, such as mobile phones or IC cards. In the production of a flash chip, at least one array area containing millions of flash memory cells and one peripheral area containing peripheral circuits for reading, writing and erasing the flash memory cells are pre-defined on the surface of the semiconductor wafer. High voltage devices are needed as peripheral circuits for writing and erasing the flash memory cells. Thus, thicker field oxide layers in the peripheral area made for high voltage devices are necessary. One way of reducing the cost of the flash chip is to make the field oxide layer in a flash memory cell smaller and thinner. So, in the production of the flash memory chip, different thickness field oxide layers are used to satisfy the high operating voltage and high cell density requirements. The field oxide layer structure with two different thickness is called a dual local oxidation structure (dual LOCOS).

Please refer to FIG. 1 to FIG. 5, FIG. 1 to FIG. 5 are the schematic diagrams illustrating the formation of the dual LOCOS according to the prior art. The method of forming dual LOCOS according to the prior art involves sequential formation of two types of field oxide layers each at a different thickness. As shown in FIG. 1, a semiconductor wafer 10 comprises a silicon substrate 12 the surface of which contains two pre-defined non-overlapping areas: peripheral area 11 and array area 13. A pad oxide layer 14 and a silicon nitride layer 16 are sequentially positioned on the surface of the semiconductor wafer. The first step in the method of forming dual LOCOS according the prior art entails a first lithography process and a first etch process to form a plurality of first recesses 18 in the peripheral area 11. As shown in FIG. 2, a first high-temperature oxidation process is performed to form a first oxide layer in each of the first recesses. As shown in FIG. 3, a plurality of the second recesses 22 in the array area 13 is formed by a second lithography and a second etch process. As shown in FIG. 4, a second high-temperature oxidation process is performed to simultaneously form a second field oxide layer 24 in each of the second recesses 22 and to increase the thickness of the first field oxide layers 20. FIG. 5 shows the final dual LOCOS.

Since the method of forming dual LOCOS according to the prior art comprises two lithography processes, two etch processes and two high-temperature oxidation processes, the procedure of making the flash memory chip is overly complex, and thus increases the manufacturing cost.

### SUMMARY OF THE INVENTION

It is therefore a primary objective of the present invention to provide a method of forming a dual LOCOS structure with only one lithography process, one etch process and one high-temperature oxidation process to simplify the process flow of the flash memory chip and reduce the cost of the IC product.

In a preferred embodiment, the present invention provides a method of forming a dual local oxidation structure (LOCOS) of a memory chip in a semiconductor wafer, the semiconductor wafer comprising a silicon substrate, non-overlapping first and second areas defined on the surface of the silicon substrate, the first area being used for forming a memory array of the memory chip, the second area being used for forming a peripheral circuit of the memory chip for controlling the operation of the memory array, the method comprising the following steps:

forming a pad silicon oxide and a silicon nitride layer on the silicon substrate having a polarity of recesses extending down to the surface of the silicon substrate, the widths of the recesses in the first area being narrower than the widths of the recesses in the second area; and

performing a high temperature oxidation process to form a field oxide layer on the surface of the silicon substrate within each of the recesses;

wherein the field oxide layer in each of the recesses in the first area is thinner than the field oxide layer in each of the recesses in the second area.

It is an advantage of the present invention that the method of forming a dual LOCOS according to the present invention only requires a lithography process, an etch process and a high-temperature oxidation process. Thus, the whole process flow is simplified and the cost is reduced.

This and other objectives of the present invention will no doubt become obvious to those of ordinary skill in the art after having read the following detailed description of the preferred embodiment which is illustrated in the various figures and drawings.

### BRIEF DESCRIPTION OF THE DRAWINGS

FIG. 1 to FIG. 5 are the schematic diagrams illustrating the formation of dual LOCOS according to the prior art.

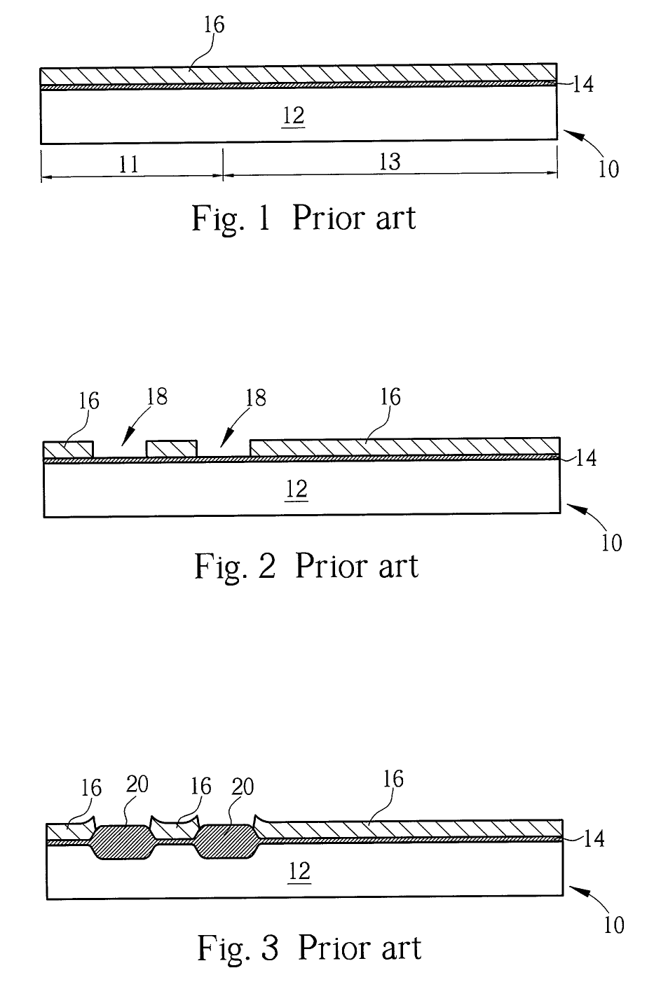

FIG. 6 to FIG. 8 are the schematic diagrams illustrating the formation of dual LOCOS according to the present invention.

FIG. 9 is the relation diagram between the thickness of the field oxide layer and the width of the recess.

FIG. 10 to FIG. 12 are the schematic diagrams illustrating the modification of the electric performances of the dual LOCOS in FIG. 8 according to the present invention.

### DETAILED DESCRIPTION OF THE PREFERRED EMBODIMENT

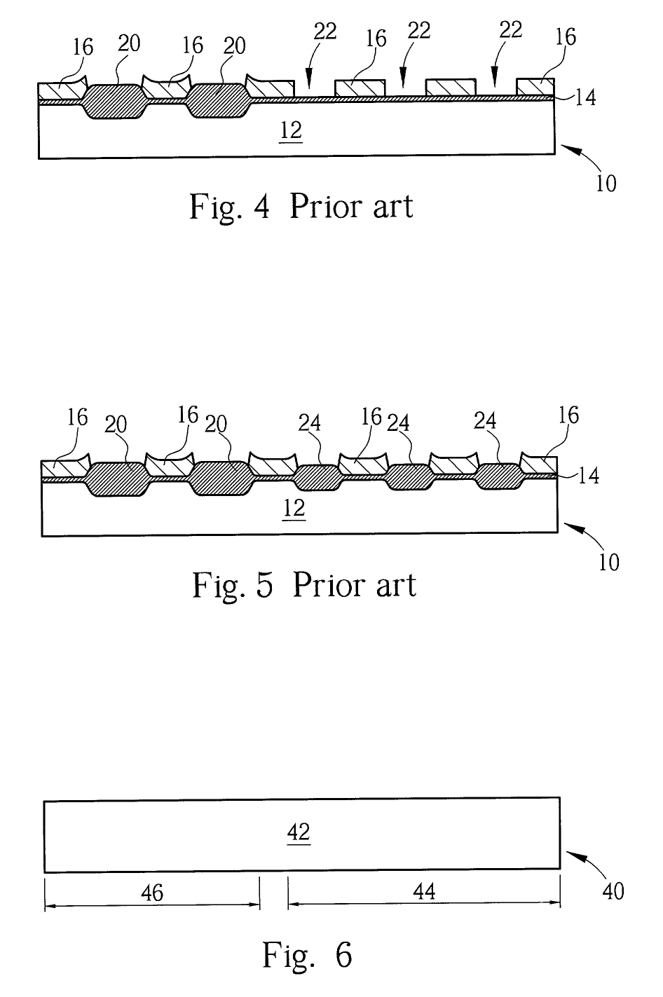

Please refer to FIG. 6 to FIG. 8. FIG. 6 to FIG. 8 are schematic diagrams illustrating the formation of dual LOCOS according to the present invention. The present invention provides a method of forming a dual local oxidation structure (LOCOS) of a flash memory chip. As shown in FIG. 6, a semiconductor wafer 40 comprises a silicon substrate 42 and non-overlapping first and second areas pre-defined on the surface of the silicon substrate 42. The first area is an array area 44 for forming an array of flash memory cells of the flash memory chip. The second area is a peripheral area for forming peripheral circuits of the flash memory chip for controlling the operation of the flash memory array.

The first step in the method of the present invention is to sequentially form a pad oxide layer 48 and a silicon nitride layer 50. The pad oxide layer 48 relieves the stress induced between the nitride layer 50 and the silicon substrate 42. A lithography process and an etch process is performed to form a plurality of recesses 52, 54 extending down to the surface of the pad oxide layer 48 in the array area 44 and the peripheral area 46. The widths of the recesses 52 in the array area 44 are all narrower than the widths of the recesses 54 in the peripheral area 46 as shown in FIG. 7. For instance, the widths of the recesses 52 are all narrower than 1.0 μm and the widths of the recesses 54 are all wider than 1.0 μm. Then, a high-temperature oxidation process is performed between 900 and 1100° C. to form a field oxide layer on the surface of the silicon substrate 42 in each of the recesses 52, 54 as shown in FIG. 8. Since the widths of the recesses 52 are narrower than the widths of the recesses 54, the field oxide 56 in each of the recesses 52 in the array area 44 is thinner than the field oxide layer 58 in each of the recesses 54 in the peripheral area 46, thus forming a dual LOCOS.

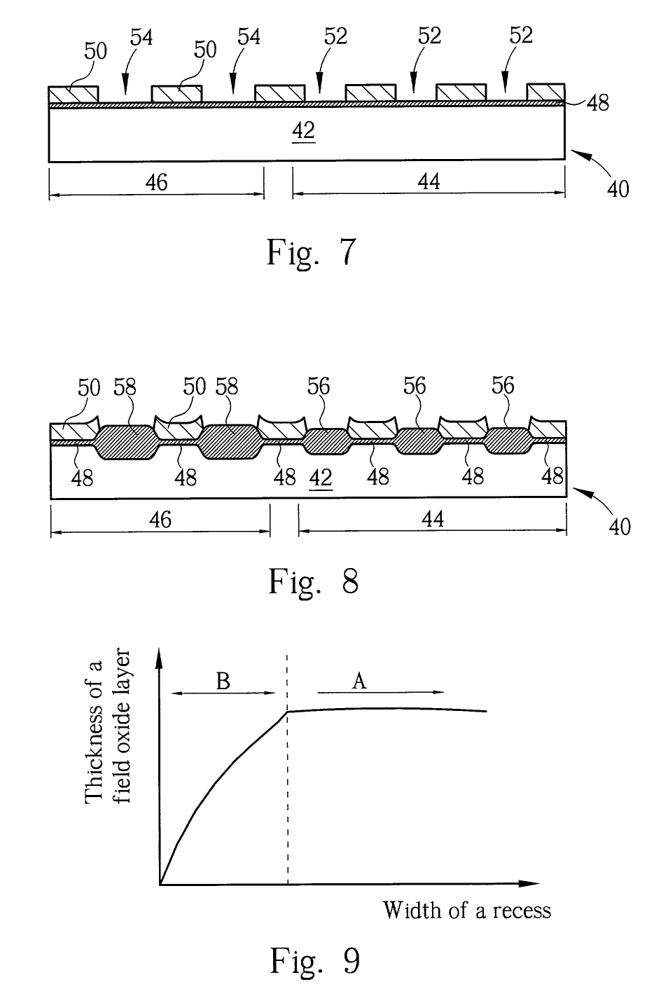

Please refer to FIG. 9. FIG. 9 is the relation diagram between the thickness of the field oxide layer and the width of the recess. As shown in region B of FIG. 9, through a fixed high-temperature oxidation process, the thickness of the field oxide layer in a recess increases along with increases in the width of the recess. As shown in region A of FIG. 9, when the width of the recess reaches a particular maximum value, the thickness of the field oxide layer becomes constant despite further variation in the width of the recess. Therefore, a constant width value in region B is selected as the widths of the recesses 52 in the array area 44 such that a thinner field oxide layer may be formed for each of the millions of memory cells. Also, width values within region A are used as width values of the recesses 54 in the peripheral area for forming thicker field oxide layers 58 for devices that can withstand high voltages. Lithography, etching, high-temperature oxidation and only slight modifications in the widths of the recesses 52, 53 are necessary to form a dual LOCOS. This helps to reduce the cost of wafer processing.

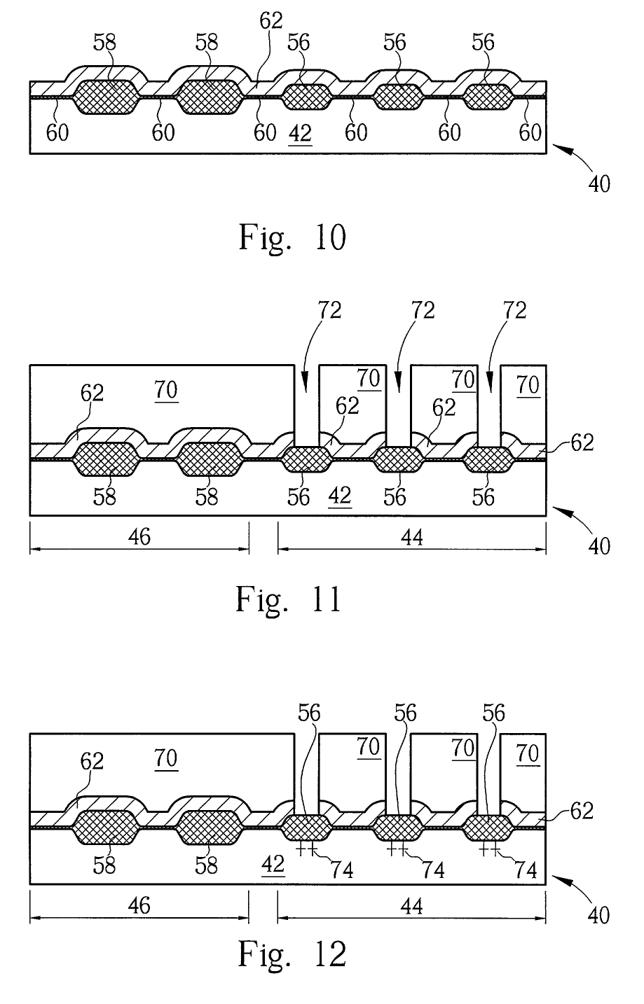

Please refer to FIG. 10 to FIG. 12. FIG. 10 to FIG. 12 are schematic diagrams illustrating the modification of the electric performance of the dual LOCOS in FIG. 8 according to the present invention. Formation of floating gates of the flash memory cells is performed after formation of the dual LOCOS is complete according to the present invention. The method of the present invention further provides a method of modifying the electric performance of the dual LOCOS and can be used in combination with the formation of the floating gates to achieve the high field threshold voltage requirement for the field oxide layers 56 in the array area 44. In the method according to the present invention a nitride stripping process is first performed to completely remove the nitride layer 50. Then, a wet etching process is performed to remove the pad oxide layer 48 followed by a gate oxidation process to form a gate oxide layer 60 on the surface of the silicon substrate 42 not covered by the field oxide layers 56, 58. The gate oxide layer 60 is a tunnel oxide layer for the tunneling of hot electrons. A deposition process is then performed to form a gate conductive layer 62 made of poly-silicon on the semiconductor wafer 40 as shown in FIG. 10. The gate conductive layer 62 in the array area 44 is used for producing the floating gates of the flash memory cells.

Then, a lithography process is performed to form a photo-resist layer 70 on predetermined areas of the semiconductor wafer 40 for covering the peripheral area 46 completely and forming a plurality of recesses 72 positioned on the field oxide layers 56 in the array area 44. An etch process is then performed to remove the gate conductive layer 62 under the recesses 72 of the photo-resist layer 70 as shown in FIG. 11. A plurality of preliminary floating gates is formed following the completion of these steps. Finally, an ion implantation process is performed to form a doped layer 74 as shown in FIG. 12. The doped layer 74 adjusts the dopant concentration of the silicon substrate 42 under the recesses 72 and improves the field threshold voltage of the field oxide layer 56 in the array area 44.

In the method of modifying the electric performances of the dual LOCOS according to the present invention, the photo-resist layer 70 is used to define the floating gates. Then, a doped layer 74 is formed by an ion implantation process to improve the field threshold voltage of the field oxide layers 56 in the array area 44 and to ensure that there is no cross-talk between the flash memory cells in the array area. Furthermore, there must be an offset between the edges of the recesses 72 and the edges of the field oxide layers 56 in the array 44 according to the layout design rule to ensure that the doped layer 74 is formed exactly under the field oxide layers 56 in the array area 44 and not in any active region in the array area 44. Thus, the junction breakdown voltages of the sources and drains in the active region can still be maintained at a high level and no degradation will occur secondary to contact between the high concentration doped layer 74 and the sources and drains of the transistors.

After forming the dual LOCOS structure, in the method of modifying the electric performances of the dual LOCOS, a photo-resist layer 70 with a plurality of recesses 72 is first formed on the field oxide layers 56 in the array area 44 by performing a lithography process. Then, an ion implantation process is performed to adjust the dopant concentration of the silicon substrate 42 under the recesses 72. Between which steps of the procedure to insert the method of modifying the electric performance is a matter of choice. It can be performed following the formation of the dual LOCOS structure or it can be inserted following the stripping of the nitride layer 50. Obviously, it can also be inserted after the floating gates of the flash memory cells are defined. If the photo-resist layer 70 is chosen such that it can also function as the mask for defining the floating gates of the flash memory cells, no additional lithography processing is necessary and cost is reduced.

In contrast to the method of forming a dual LOCOS according to the prior art, the method according to the present invention forms field oxide layers 56, 58 of different thickness through the modification of the widths of the recesses 52, 54. Only a lithography process, an etch process and a high-temperature oxidation process are needed to form a dual LOCOS. Thus the whole process flow is simplified and cost is reduced. Also, a method for modifying the electric performance of the dual LOCOS is also provided in this invention. This method can be applied during definition of the floating gates of the flash memory cells. Using the doped layer 74 formed through an ion implanting process, the electric performance of the dual LOCOS can be greatly improved without any negative impact on the devices in the active region.

Those skilled in the art will readily observe that numerous modifications and alterations of the device may be made while retaining the teaching of the invention. Accordingly, the above disclosure should be construed as limited only by the metes and bounds of the appended claims.

What is claimed is:

1. A method of forming a dual local oxidation structure (LOCOS) of a memory chip in a semiconductor wafer, the semiconductor wafer comprising a silicon substrate, non-overlapping first and second areas defined on the surface of the silicon substrate, the first area being used for forming a memory array of the memory chip, the second area being used for forming a peripheral circuit of the memory chip for controlling the operation of the memory array, the method comprising the following steps:
forming a silicon nitride layer on the silicon substrate having a polarity of recesses extending down to the surface of the silicon substrate, the widths of the recesses in the first area being narrower than the widths of the recesses in the second area; and
performing a high temperature oxidation process to form a field oxide layer on the surface of the silicon substrate within each of the recesses;
wherein the field oxide layer in each of the recesses in the first area is thinner than the field oxide layer in each of the recesses in the second area.

2. The method of claim 1 wherein the temperature of the major step in the high-temperature oxidation process is between 900 and 1100° C.

3. The method of claim 1 wherein the widths of all the recesses in the first area measure are less than 1.0 μm.

4. The method of claim 1 wherein the semiconductor wafer further comprises a pad oxide layer positioned between the nitride layer and the silicon substrate for relieving stress induced between the nitride layer and the silicon substrate.

5. The method of claim 1 wherein the first area is used for forming a plurality of flash memory cells.

6. The method of claim 1 wherein the method further comprises the following steps after the formation of the field oxide layers:
performing a lithography process to form a photo-resist layer with a plurality of recesses positioned on the field oxide layers in the first area; and
performing an ion implantation process to adjust the dopant concentration of the silicon substrate under the recesses of the photo-resist layer.

7. The method of claim 6 wherein the first area is used for forming a plurality of flash memory cells.

8. The method of claim 6 wherein the method further comprises the following steps between the formation of the field oxide layer and the lithography process:
performing a nitride stripping process to completely remove the nitride layer;
performing a wet etching process to remove the pad oxide layer;
performing a gate oxidation process to form a gate oxide layer on the surface of the silicon substrate not covered by the field oxide layer; and
performing a deposition process to form a gate conductive layer on the semiconductor wafer.

9. The method of claim 8 wherein the gate conductive layer is made of poly-silicon.

10. The method of claim 8 wherein the photo-resist layer completely covers the second area of the semiconductor wafer.

11. The method of claim 10 wherein the method further comprises the following step after the lithography process:
performing an etch process to remove the gate conductive layer under the recesses of the photo-resist layer.

12. The method of claim 10 wherein the first area is used for forming a plurality of flash memory units and the gate conductive layer is used for forming the floating gate of each of the flash memory cells.
